(19) United States
(12) Patent Application Publication
(10) Pub. No.: US 2022/0134588 A1
(43) Pub. Date: May 5, 2022

(54) RAZOR BLADES WITH CHROMIUM BORIDE-BASED COATINGS

(71) Applicant: The Gillette Company LLC, Boston, MA (US)

(72) Inventors: Andrew Vladimirovich Zhuk, Berlin, MA (US); Ronald Richard Duff, JR., Shrewsbury, MA (US)

(21) Appl. No.: 17/517,793

(22) Filed: Nov. 3, 2021

Related U.S. Application Data
(60) Provisional application No. 63/109,263, filed on Nov. 3, 2020.

(51) Int. Cl. B26B 21/60; C23C 14/34; C23C 14/06

(52) U.S. Cl. CPC B26B 21/60; C23C 14/067; C23C 14/3464; C23C 14/34

(57) ABSTRACT

This invention relates to a novel application of a compound of chromium and boron, or the application of chromium boride-based coatings (e.g., CrBₙ where an atomic percentage of boron ranges from greater than zero atomic percent to less than 100 atomic percent of said compound) to surfaces of razor blades, namely cutting edges. On razor blade edges, these novel coatings are hard, durable, and provide a novel, low cutter force and high-quality coating structure, elevating blade performance, while also simplifying the manufacturing process.

### FIELD OF THE INVENTION

The apparatus relates generally to razor blades, and more particularly, to novel coatings on razor blade edges.

### BACKGROUND OF THE INVENTION

Current razor blades typically include a sharpened substrate, such as stainless-steel, a hard coating(s) to optimize edge strength, tip shape, wear resistance, etc. layered on top of the stainless-steel and a soft coating(s) generally of polymeric material, such as polytetrafluoroethylene (PTFE), layered on top of the hard coating(s) to impart lubricity.

It is generally known that the combination of the sharpened blade profile and the hard and lubricious coatings generally define the performance of the razor blade element. Generally, of interest are coating options which may improve a blade element's hard coating performance and/or decrease the cutter force.

It would be desirable to optimize blade coatings and/or steps required in the blade production, while maintaining or improving blade performance.

### SUMMARY OF THE INVENTION

In accordance with the present invention, a razor blade apparatus includes a sharpened substrate having at least one material including a compound of chromium and boron, (CrBₙ) disposed thereon, wherein an atomic percentage of boron ranges from greater than zero atomic percent to less than 100 atomic percent of the compound.

In a preferred construction of the present invention, the at least one layer of CrBₙ material is directly disposed on the sharpened substrate and the at least one CrBₙ material forms at least one layer on the sharpened substrate. One or more interlayers can be disposed between the at least one CrBₙ layer and the sharpened substrate and one or more overcoat layers may be disposed on top of the at least one CrBₙ layer, or both.

The one or more interlayers and the one or more overcoat layers may be comprised of polymeric material, niobium, chromium, platinum, titanium, silicon, tantalum, tungsten, molybdenum, carbon, boron, or any combination or alloys thereof.

In an embodiment of the present invention, at least one polymeric material is disposed on top of the at least one CrBₙ layer or on top of the one or more overcoat layer, or any combination thereof. The polymeric material includes PTFE.

In another embodiment, the one or more overcoat layers can be comprised of a CrBₙ material and an additive or a second component. The additive can be one or more of a polymeric material, ceramic, metal, silicon, boron, carbon, or any combination thereof.

In another aspect of the present invention, the one or more overcoat layers include an increasing concentration of the additive in a direction towards an outer surface of the substrate or a decreasing concentration of the second component in a direction towards an outer surface of the substrate.

The at least one CrBₙ layer of the present invention is disposed on the sharpened substrate via physical vapor deposition or chemical vapor deposition, or any combination thereof. The sharpened substrate may include stainless-steel, metal, ceramic, composite, diamond, silicon, polymeric material, glass, or any combination thereof. The substrate can be martensitic stainless steel having a carbide density of about 90 carbides per 100 square micrometers to about 1000 carbides per 100 square micrometers. In one aspect, the sharpened substrate is disposed on a blade edge of a razor blade wherein the blade edge is linear, non-linear, or any combination thereof.

In another aspect of the invention, the at least one CrBₙ layer has a hardness greater than or equal to 15 GPa.

In a preferred aspect, the at least one CrBₙ layer includes a substantially dense, smooth, columnar-free structure, or any combination thereof, a tip radius of the razor blade ranging from 100 Angstroms to 1000 Angstroms, a cutter force of the razor blade ranging from 0.5 lbs. to 2 lbs, and a thickness of the layer ranging from 50 Angstroms to 5000 Angstroms.

A method of making a razor blade includes providing a sharpened substrate and depositing at least one layer of CrBₙ material on an outer surface of the substrate.

The deposition may include sputtering, such as by Physical Vapor Deposition or Chemical Vapor Deposition or any combination thereof. There may be a negative voltage on the substrate. The negative voltage can range from less than or equal to 0V to negative 1000V (−1000 VDC). The depositing step includes providing one or more targets. The one or more targets may include a homogeneous mixed material including chromium and boron or two targets, one including chromium and one including boron.

The method of making produces a coating on the razor blade having a thickness of the layer ranging from 50 Angstroms to 5000 Angstroms, a cutter force of an edge of the razor blade ranging from 0.5 lbs. to 2 lbs, a tip radius of a tip of the razor blade ranging from 100 Angstroms to 1000 Angstroms. In a preferred aspect, the at least one layer of CrBₙ material includes a substantially dense, smooth, columnar-free structure, or any combination thereof.

In another aspect of the invention, at negative voltage ranges between −250 VDC and −1000 VDC, a tip radius is produced ranging from 200 to 300 Angstroms, and at the negative voltage ranges between 0 VDC and −250 VDC, a tip radius is produced that is greater than 300 Angstroms. The thickness of the at least one layer of CrBₙ material ranges from 300 A to 800 A.

In one aspect, at a negative voltage ranging from about −250 VDC and −1000 VDC, a cutter force of the razor blade is produced ranging from about 0.6 lbs. to about 1.0 lbs. and at a negative voltage ranging between 0 VDC and −250 VDC, a cutter force of the razor blade is produced that is greater than 1.0 lbs.

In a yet further embodiment of the invention, a method of coating a razor blade is provided including the steps of providing a sharpened substrate, depositing at least one layer of material on the sharpened substrate, the deposition including sputtering and providing a voltage on the substrate, and selecting a first voltage range on the substrate to produce a first razor blade edge or a second voltage range on the substrate to produce a second razor blade edge, the second razor blade edge being sharper than the first razor blade edge.

The first razor blade edges have tip radii larger than tip radii of the second blade edges. The first and second voltage ranges range from 0V to negative 1000V (−1000 VDC). The first voltage range ranges between 0 VDC and −250 VDC and the second voltage range ranges between about −250 VDC and −1000 VDC.

In another aspect, a first tip radius of the first razor blade edge produced is greater than 300 Angstroms and a second tip radius of the sharp blade edge produced is less than 300 Angstroms.

In yet another aspect, a cutter force of the first razor blade edge is greater than 1 lbs and a cutter force of the second blade edge ranges from about 0.5 lbs. to about 1 lbs.

In a yet further embodiment, the layer of material comprises chromium, boron, carbon, titanium, tantalum, or any combination thereof.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

Other features and advantages of the invention will be apparent from the following detailed description, and from the claims.

### BRIEF DESCRIPTION OF THE DRAWINGS

While the specification concludes with claims particularly pointing out and distinctly claiming the subject matter which is regarded as forming the present invention, it is believed that the invention will be better understood from the following description which is taken in conjunction with the accompanying drawings in which like designations are used to designate substantially identical elements, and in which:

FIG. 1 is a perspective view of a razor having a cartridge and a handle and blade edges having CrBₙ disposed thereon in accordance with the present invention.

FIGS. 2-11 are each a diagrammatical view of a blade edge of FIG. 1 in accordance with the present invention.

FIG. 12 is a micrograph image of the CrBₙ material of the present invention disposed on a razor blade depicting characteristics of the CrBₙ coating.

FIG. 13 is a micrograph image of a prior art hard coating disposed on a razor blade depicting characteristics of the hard coating.

FIG. 14 are SEM micrograph images taken at 50K magnification of the CrBₙ material disposed on a razor blade and resultant characteristics of the blade edge in accordance with the present invention.

FIG. 14a are diagrams of an average of multiple edge profiles for each of the blades depicted in FIG. 14.

FIG. 14b is a diagram of the coated razor blade of the present invention illustrating the method for determining the tip angle of the coated blade.

FIG. 15 is a diagram of the coated razor blade of the present invention illustrating the method for determining the tip radius of the coated blade.

FIG. 16 is a perspective view of dry shaver components having a CrBₙ material disposed thereon in accordance with the present invention.

### DETAILED DESCRIPTION OF THE INVENTION

This invention relates to a novel application of chromium borides, known as CrBₙ, where the atomic percent of boron in the compound ranges from greater than zero atomic percent to less than 100 atomic percent. The value for n of the present invention, for instance, can be any number such as ½, 2, or 4. With n equal to 2, as just one example, a CrB₂ based ceramic coating is applied to surfaces of razor components (e.g., retaining clips, cartridge housing) and in particular to blade edges of razor blades, as described herein. Applicants discovered the beneficial use of CrBₙ materials with razor blades. Shaving requirements for hard coatings are not analogous to the requirements for wear protective coatings on larger tools, due to many factors such as the nature of deposition on a blade edge (e.g., blade edges are angled), the much smaller size of the razor blade and edge surface which is coated (e.g., on the micrometer scale), the processes used to produce these coatings, and the fact that what is desired in shaving is a hard blade edge capable of cutting something soft like hair on a movable surface like skin, without cutting the skin.

The hardness, strength, and the structural properties of the CrBₙ coating, in addition to the surprising tip shaping capabilities of the blade edge coating over blade edge coatings of the prior art provide significant benefits on razor blade edges, such as very low cutter forces and thus it is felt that these coatings elevate blade performance while also simplifying the manufacturing process.

Razor blades in accordance with the present disclosure may comprise a coating disposed substantially on the outer sides of the razor blade. A “layer” as used herein may signify at least one material on a razor blade satisfied by a variety of factors, including but not limited to, the composition, morphology, or structure of the layer(s); the presence of a boundary between layers; whether the process used to make the product is expected to result in one or more layers; and whether there is a sufficient change in composition or morphology as to result in one or more layers. As one example, there may be only one type of material on the razor blade but with distinguishable layers, each layer having a different morphology. As used herein, a “coating” may signify one or more layers on a razor blade, in which each layer comprises one or more materials. Thus, the present invention “coating” may be defined by a single layer or by multiple layers. The present invention also contemplates the term “coating” to signify the overall or total coating on one side of the razor blade, which includes all of the layers on that one side of the razor blade.

In particular, a “coating” as used herein includes all layer(s) of material(s) applied to one outer side of the razor blade. For example, a coating may include one or more layers as defined herein, such as a first layer that is disposed substantially on a portion or the entirety of one outer side of the razor blade; a second layer that is formed on top of at least a portion of the first layer; a third layer that is formed on top of at least a portion of the second layer; and so on.

Baseline chromium boride material is a compound that generally contains elemental chromium and boron. The terms “CrBₙ” or “CrBₙ material” or “CrBₙ layer” or “chromium-boride” or “chromium-boride-based” or “CrBₙ alloy” will generally be used interchangeably herein and may signify the base materials as a compound of chromium and boron, or a variant of the material where the atomic percent of boron ranges from greater than zero to less than 100 in said compound. For instance, in the metal boride CrB₂, n has a value of 2.

Also contemplated in the present invention is a material comprised of the base compound CrBₙ, combined with a variety of single or multi-element additives, alloys, or agents which may have some impact on its properties. CrBₙ without additive components is sometimes called base or baseline material to distinguish it from a CrBₙ material containing second phase or solid solution additives or other elements. The additives may generally include, though would not be limited to, components such as one or more of a polymeric material, a ceramic material, a metal, silicon, boron, carbon, or any combination thereof.

In the present invention, these additives may be evenly dispersed through the CrBₙ layer or may increase or decrease in amount in the direction towards the outer surface of the deposited coating.

CrBₙ is a chemical compound of chromium and boron, and is a ceramic that is largely highly resistive to wear and corrosion. It should be noted that CrBₙ material may generally become harder when certain elements or compounds are added to the CrBₙ baseline material. It is contemplated that additives, such as those mentioned supra may increase the microhardness to greater than 35 GPa, thereby producing an even harder material, if desired and feasible. For instance, baseline CrBₙ material may typically display microhardness of greater than about 15 GPa, generally greater than about 30 GPa, or about 32 GPa to about 40 GPa.

CrBₙ materials have demonstrated superb adherence to stainless-steel. When directly disposed on a stainless-steel substrate of a razor blade, CrBₙ materials generally do not delaminate or otherwise wear away. CrBₙ materials have also advantageously demonstrated high hardness, (e.g., greater than 15 GPa) when disposed on a razor blade edge.

In one embodiment of the invention, CrB₂ material coatings on a razor blade edge have exhibited extremely dense, columnar-free tip areas with smoothness and with high hardness (greater than 15 GPa) resulting in superb cutter forces and beneficially good corrosion resistant properties.

Consequently, a coating on a razor blade comprising CrBₙ has the potential to exceed functionality of the current discrete hard coatings applied to razor blade edges by providing a single coating, thus saving cost and time. Since the CrBₙ coatings will generally be hard and adherent, they may desirably provide a single hard coating solution for blade edges. The need for a soft lubricious overcoat layer may generally be necessary but other interlayers of materials to enhance adhesion to the substrate or to the soft lubricious outer coating or to mitigate tip rounding during shaving or the like, may or may not be sought-after, depending on desired attributes of the blade edges and characteristics of the applied CrBₙ coating. Not having additional layers, potentially eliminates required processing steps of those layers, resulting in simplified manufacturing while potentially yielding a product with enhanced performance.

Furthermore, the hardness of CrBₙ coatings on razor blades generally results in several improvements to the blade for shave performance. CrBₙ coatings applied to standard sharpened blade substrates or geometries may be comparable or outperform current hard coatings providing enhanced edge strength and wear resistance. CrBₙ coatings may also be applied to different blade profiles which may result in further optimized blade performance.

The apparatus for processing blades with the CrBₙ material desirably includes processes which are used currently, namely sputtering. Physical Vapor Deposition (PVD) techniques such as magnetron sputtering, continuous or pulsed DC sputtering, RF sputtering, or cathodic arc deposition can be utilized, however other feasible methods known in the art such as Chemical Vapor Deposition (CVD), are also contemplated as applicable processing techniques in the present invention. Substrate bias voltages during sputtering using the present invention process ranges from about 0V to negative 1000 volts DC (−1000 VDC).

The targets containing the source material to be deposited on the blades used in sputtering chambers of the present invention can preferably be formed as homogeneous or mixed material targets in that both chromium and boron are comprised in one target, however distributed, or formed as individual areas of chromium and individual areas of boron in one target (e.g., a patchwork format). Co-sputtering is also contemplated in the present invention, where two or more individual source materials are sputtered from separate targets, either at once or in sequence in the vacuum chamber. Additionally, cathodic arc deposition can be utilized to deposit CrBₙ.

Accordingly, the novel coating of the present invention can be deposited at different ratios between chromium and boron. Preferable compositions of the present invention comprise Cr₂B or CrB_{1/2}, CrB, CrB₂, and CrB₄ but other ratios are contemplated and may be desirable for specific shaving applications.

In the present invention, the concentration of boron can range from a very low concentration (just over 0 atomic percent) to a very high concentration of less than 100 atomic percent.

CrBₙ coatings deposited on blade substrates beneficially provide for the formation of a much wider range of possible tip shapes than the prior art. This is because it was discovered that the resultant coating tip geometry is highly sensitive to the substrate bias voltage applied during the sputtering process. For instance, at a substrate bias voltage in the range between 0 VDC and −250 VDC, the tip shape is blunt or rounded having a tip radius of generally greater than 300 Angstroms and at a substrate bias voltage range between −250 VDC and −1000 VDC, the tip shape is extremely pointed or sharp having a tip radius generally less than or equal to 300 Angstroms.

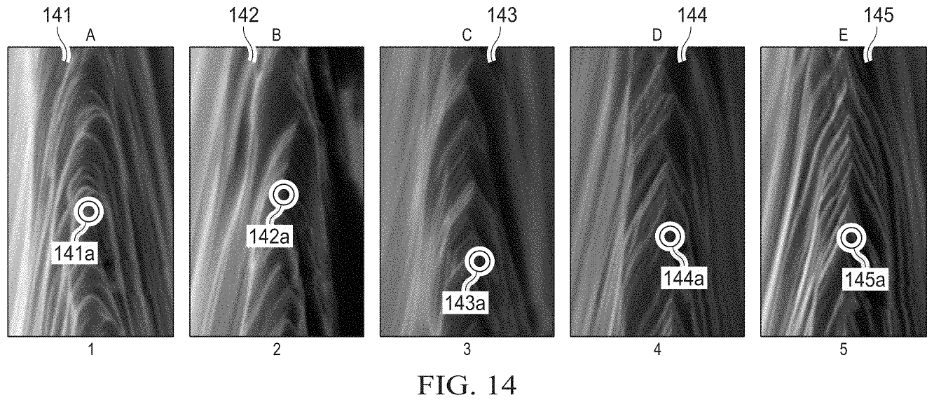

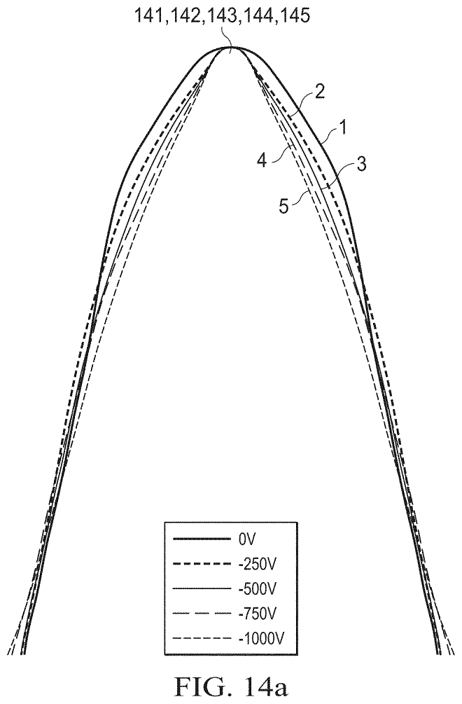

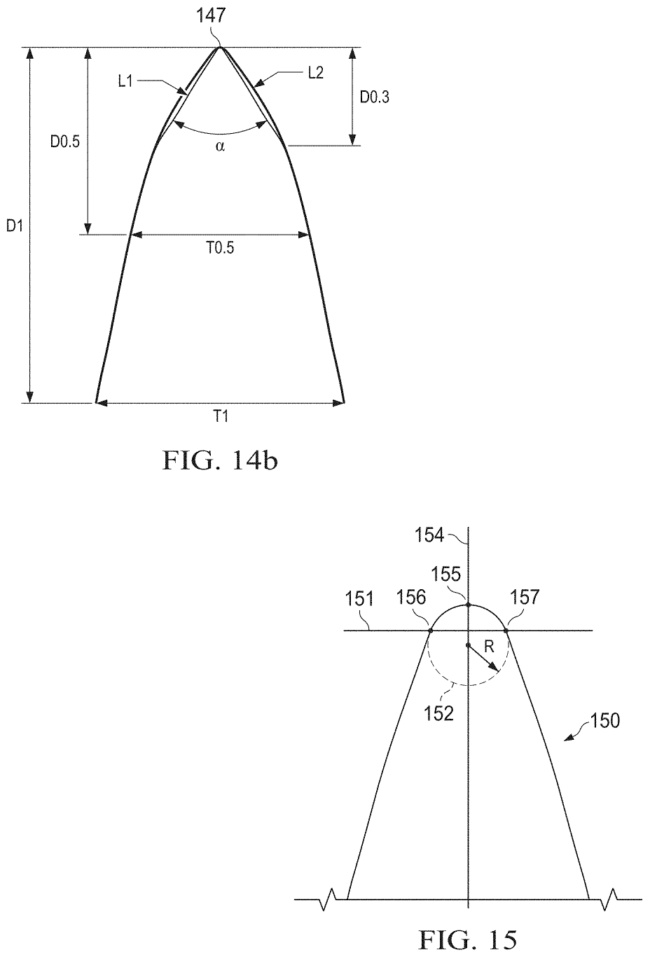

The resultant tip shapes of the present invention range from rounded to very sharp as shown in FIG. 14 (micrographs), described below.

While stainless-steel is the desired substrate of the present invention, as it is the common substrate for razor blades, blade substrates comprised of another metal or metals, ceramic, polymeric materials, glass, diamond, silicon, or any combination thereof, are also contemplated in the present invention.

One substrate material which may facilitate producing an appropriately sharpened edge is a martensitic stainless-steel with smaller more finely distributed carbides, but with similar overall carbon weight percent. A fine carbide substrate provides for a harder substrate with enhanced hardenability, with more brittleness after-hardening, and enables the making of a thinner, stronger edge. An example of such a substrate material is a martensitic stainless-steel with a finer average carbide size with a carbide density ranging from about 90 carbides per 100 square micrometers to about 1000 carbides or more per 100 square micrometers as determined by Scanning Electron Microscope (SEM). A cross-section image can be obtained by SEM at 4000 magnification or higher.

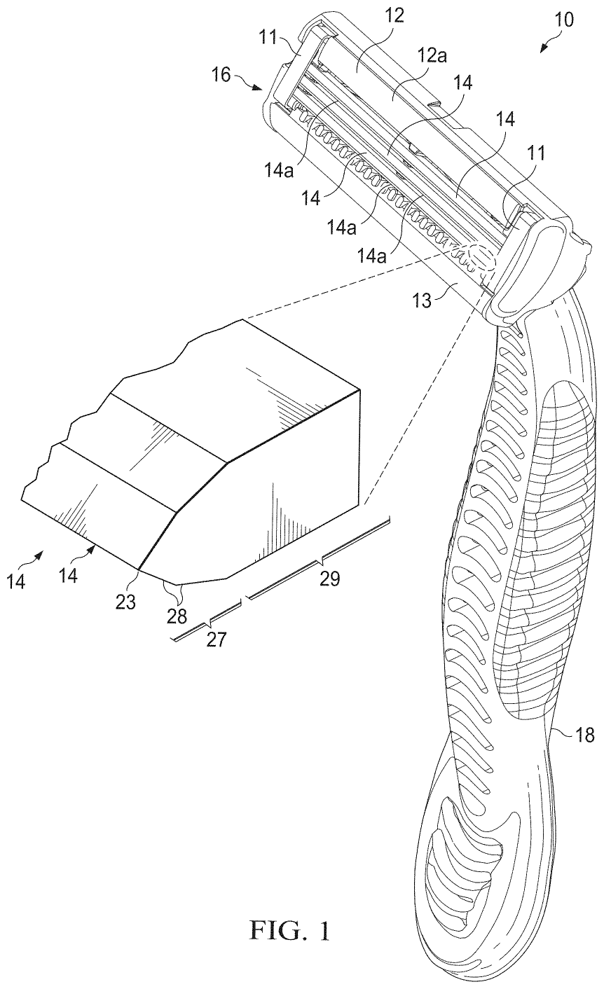

The term “razor blade” in the present invention desirably signifies a “substrate” comprised of stainless-steel which includes a blade body and at least one flank. Desirably, a razor blade includes two flanks forming a blade edge and a blade body. The two flanks intersect at a point or tip, or what is oftentimes referred to as the ultimate tip. Each flank may have one, two or more bevels. The blade body is generally the remaining area of the razor blade beneath the flanks or bevels. As shown in a call-out section of FIG. 1, blade 14 includes blade body 29, two bevels 28 for each of two flanks 27 which intersect at tip 23 forming a blade edge 14a. A “substrate” signifies the substance or material acted upon in the present invention. Illustrative embodiments herein relate to a stainless-steel substrate, commonly used for razor blade formation.

Turning now to FIG. 1, a razor 10 generally includes a shaving or cartridge unit 16 attached to a handle 18 with the shaving unit 16 having one or more blades 14 (e.g., 3 blades shown) each with a sharpened edge 14a in accordance with the present invention. A cap 12 and guard 13 may also be included in the shaving unit 16, the cap 12 preferably including a shaving aid composite 12a affixed thereon. The shaving unit 16 may be adapted for coupling and uncoupling from the razor handle 18 such that a new cartridge unit 16 may be coupled to the handle when the blades become dull or may be integral with a handle 18 so that the complete razor 10 is discarded when the blades become dull. It is noted that one or more of the blades 14 in FIG. 1 has a CrBₙ material disposed thereon, preferably on the blade edge region.

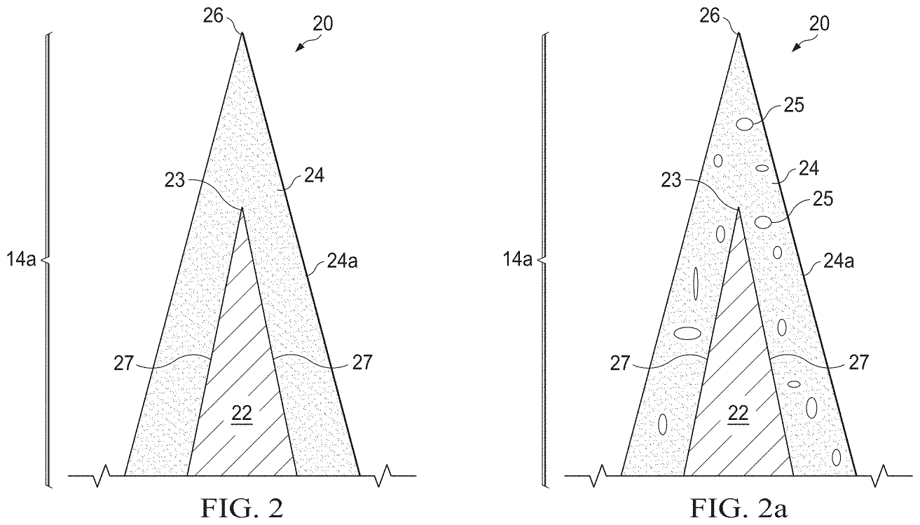

A diagrammatic view of a blade or sharpened substrate, and in particular the blade edge region 20 of blade edge 14a of FIG. 1, is shown in FIG. 2 of the present invention. The blade includes a stainless-steel substrate 22 with a sharpened edge formed in a sequence of honing operations that forms a tip portion 23 with a radius typically less than 500 Angstroms and edge flanks 27 which may or may not include one or more bevels 28 as shown in the call-out section of FIG. 1. Deposited on the tip 23 and flanks 27 of substrate 22 is at least one layer 24a comprising CrBₙ material 24 in accordance with a preferred embodiment of the present invention. The thickness of the CrBₙ material 24 may desirably range from about 50 Angstroms to about 5000 Angstroms and preferably range from about 400 Angstroms to about 1800 Angstroms and may or may not be uniformly deposited throughout the tip and flanks. It should be noted that the CrBₙ material may be deposited despite any variation in lengths of flanks 27, angles, and aspect ratios (e.g., the ratio of the distance from the blade tip portion 23 to the tip 26 and the width of CrBₙ material coating 24 at the tip portion 23).

As shown in a first alternative embodiment in FIG. 2a, the layer 24a may also be comprised of one or more additives or second components 25 in addition to the CrBₙ material 24. The additives or second components 25 of the present invention include, but are not limited to, one or more of a, polymeric material, ceramic, metal, silicon, boron, carbon, or any combination thereof. Accordingly, chromium nitride (CrN), titanium boride (e.g., titanium diboride or TiB₂), aluminum nitride (AlN), boron nitride (BN), and/or alloying agents are contemplated in the present invention.

The CrBₙ coating may extend from the ultimate tip to any length down the blade edge flanks 27 and may or may not extend to the blade body 29. In a preferred embodiment of the present invention, the value of n in the CrBₙ coating is 2, with the formula CrB₂, and often referred to as chromium diboride. In another preferred embodiment of the present invention, the value of n in the CrBₙ coating (e.g., the amount of boron) is increased or decreased, e.g., n=1 or n=4, with the formula CrB or CrB₄, respectively, to achieve desired properties.

The hardness of coating 24 is generally greater than 15 GPa.

The novel coating of the razor blade of the present invention also provides an improvement in blade sharpness. The blade sharpness may be quantified by measuring cutter force, which correlates with sharpness. Cutter force is measured by the wool felt cutter test, which measures the cutter forces of the blade by measuring the force required by each blade to cut through wool felt. Each blade is cut through wool felt 5 times and the force of each cut is measured on a recorder. The lowest of 5 cuts is defined as the cutter force.

Commercially available blades generally have blade cutter forces ranging from about 1.10 lbs. to about 1.60 lbs. The cutter force of blade edge region 20 having coating 24 disposed thereon is surprisingly generally much less than commercially available razor blades having a diamond-like coating (e.g., DLC). For instance, the present invention blades with CrB₂ disposed thereon, such as the finished blades depicted in FIGS. 2-10 generally result in cutter forces ranging from about 0.5 lbs. to 2 lbs, preferably less than 1 lbs., or about 0.60 lbs. to about 1.00 lbs, and more preferably about 0.69 lbs. to about 0.98 lbs. This latter range of cutter forces was obtained for bias voltages ranging from negative 250 VDC (−250 VDC) to negative 750 VDC (−750 VDC) and a CrB₂ coating thickness greater than about 500 Angstroms.

As shown in FIG. 12, which will be discussed in detail below, exemplary CrBₙ coatings of the present invention are depicted having a substantially dense, columnar-free area near the ultimate tip with a smooth surface.

In addition, due to the presence of boron in the CrBₙ layer 24, the CrBₙ layer 24 provides an anti-corrosive barrier that is much higher than pure chromium while also providing a safe and durable blade to a user's skin.

As noted above, the apparatus for processing blades shown in FIGS. 2-10 may desirably include magnetron sputtering including pulsed sputtering conditions, while other feasible methods known in the art are also contemplated as applicable processing techniques in the present invention.

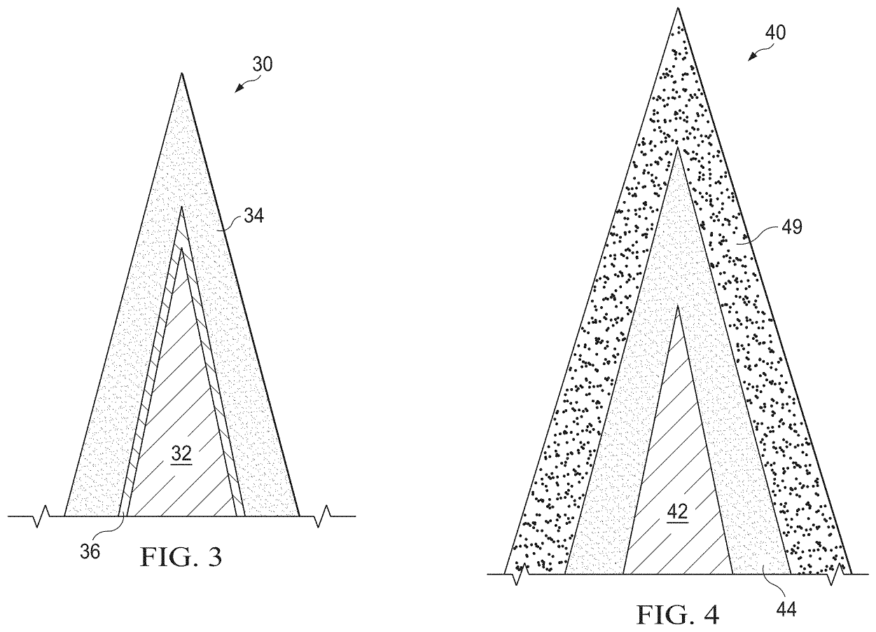

In a second alternate embodiment of the present invention, FIG. 3 depicts blade edge region 30 having one or more interlayer 36 disposed between a CrBₙ material coating or layer 34 and a stainless-steel substrate 32. The interlayer 36 may desirably include, if necessary, a material which may assist in adhesion between the CrBₙ material 34 and the stainless-steel substrate 32 and which may include niobium, chromium, platinum, titanium, silicon, tantalum, tungsten, molybdenum, carbon, boron, or alloys of the aforementioned and/or any combination thereof.-The interlayer 36 may have a thickness of about 50 Angstroms to about 5000 Angstroms. The interlayer 36 may be desirably disposed between the substrate 32 and the CrBₙ material coating 34 to assist in adherence of the CrBₙ coating 34 to the substrate 32 and may provide added strength or rigidity to the edge region 30.

In a third alternate embodiment of the present invention, FIG. 4 depicts a blade edge region 40 with one or more layers 49 (e.g., often referred to as an overcoat layer) disposed on top of the CrBₙ material layer 44 which is disposed on top of the stainless-steel substrate 42. In the present invention, the overcoat layer 49 (and other polymeric layers described herein) may desirably be comprised of a polymeric material that is generally highly lubricious, such as a fluoropolymer (e.g., polytetrafluoroethylene telomer, oftentimes referred to as PTFE) or may be comprised of a polymeric material or other materials that is/are generally more or less lubricious (e.g., having a coefficient of friction lesser or greater than that of the PTFE, respectively). Providing a telomer (e.g., PTFE) on the outermost surface of the blade edge endows a user's skin with lubriciousness on contact. The lubricious overcoat layer 49 of FIG. 4 and other similar layers described herein may have a thickness ranging from about 50 Angstroms or higher.

Thus, in the present invention, even while the CrBₙ layer 44 innately may generally provide hard and anti-corrosive properties, lubricity or augmented lubricity may be desired to provide adequate or enhanced shaving attributes (e.g., glide, less tug and pull), and as such a lubricious material such as PTFE may be added to the edge region 40 on top of the CrBₙ layer 44. Different properties on blade edges may be desirable in a blade unit.

As shown in a fourth alternate embodiment of the present invention in FIG. 5, the embodiment of FIG. 4 may include a stainless-steel substrate 52 and one or more overcoat layers 58 which may be comprised of polymeric material, niobium, chromium, platinum, titanium, silicon, carbon, tantalum, tungsten, molybdenum, boron, or alloys of the aforementioned and/or any combination thereof. The one or more overcoat layers 58 may have a thickness of about 50 Angstroms to about 5000 Angstroms. The overcoat layer 58 may be desirable to assist in adhering the polymeric layer or PTFE layer 59 onto the CrBₙ material layer 54, which is disposed on substrate 52 for providing added strength to the edge region 50.

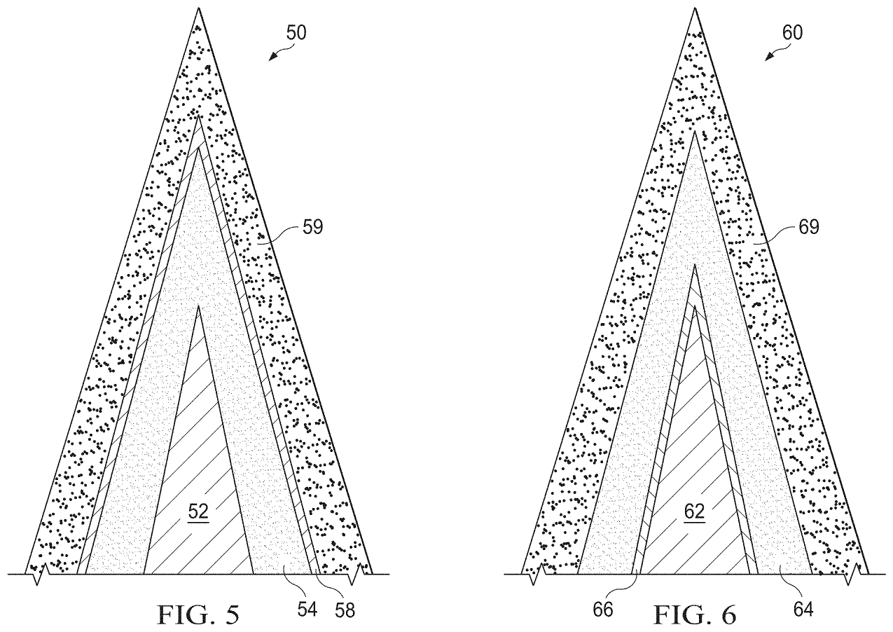

In a fifth alternate embodiment of the present invention shown in FIG. 6, the embodiment of FIG. 4 is modified depicting a blade edge region 60 with one or more polymeric overcoat layers 69 disposed on top of CrBₙ material layer 64 and one or more interlayers 66 disposed between the CrBₙ layer 64 and the substrate 62. As above, the outer layer 69 may desirably be comprised of a polymeric material such as PTFE while interlayer 66 may desirably comprise niobium, chromium, platinum, titanium, silicon, tantalum, tungsten, molybdenum, carbon, boron, or alloys of the aforementioned and/or any combination thereof. The layer 66 may have a thickness in the range of about 50 Angstroms to about 5000 Angstroms. By its location, the interlayer 66 may desirably assist in adherence of the CrBₙ material in CrBₙ layer 64 to the substrate 62 and may provide added strength or rigidity to the edge region 60. The polymeric outer layer 69 may desirably provide lubriciousness to the outermost surface which touches a user's skin thereby imparting a more comfortable shave.

The sixth embodiment shown in FIG. 7 is a modification of FIG. 6 and includes blade edge region 70 which is substantially identical to the blade edge region 60 having a substrate 72, a CrBₙ layer 74, an interlayer 76 of the type described supra, and a polymeric overcoat layer 79 with the only difference from FIG. 6 being the addition of another overcoat layer 78. The newly added overcoat layer 78 is of the type described previously in conjunction with FIG. 5's overcoat layer 58.

The overcoat layer of polymeric material of the present invention may be partially removed if desired to provide a thinner layer using any known methods and for example, U.S. Pat. No. 5,985,459, entitled Method of Treating Razor Blade Cutting Edges, issued on Nov. 16, 1999, assigned to the assignee hereof, is incorporated by reference in its entirety.

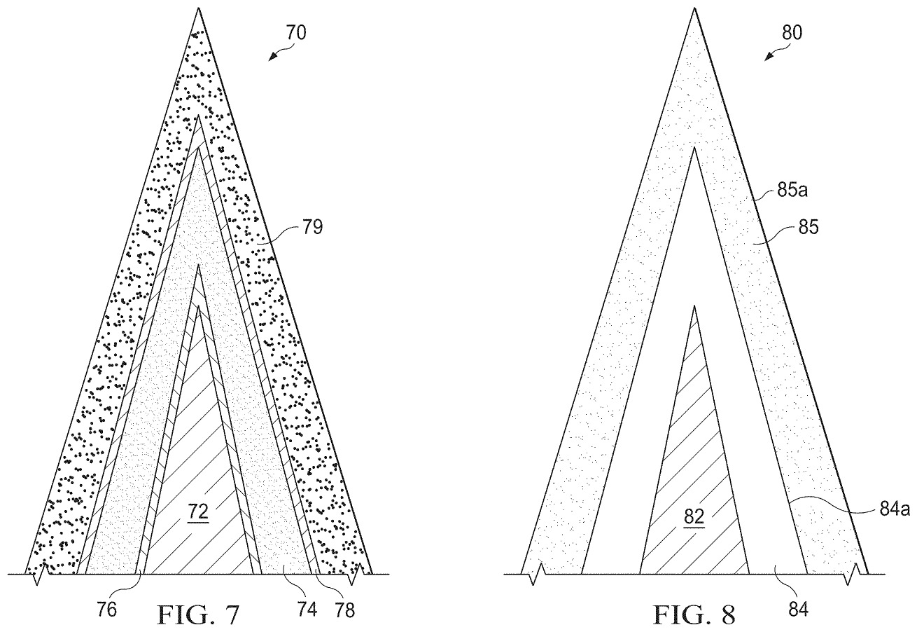

Referring now to FIG. 8, yet another embodiment of the present invention edge region 80 is depicted where at least one CrBₙ layer 84 is disposed over the substrate 82 (as in FIG. 2), but in FIG. 8, at least one CrBₙ overcoat layer 85 is additionally disposed on CrBₙ layer 84. The CrBₙ overcoat layer 85 comprises a composite including the CrBₙ material and at least one other element or compound. The latter material can be desirably comprised of one or more ceramic materials. The at least one other element (or additive) can also be comprised of one or more of a polymeric material (e.g., PTFE), metal, silicon, boron, carbon, or any combination thereof. An outer layer 86 of a polymeric material (e.g., PTFE) may be disposed over layer 85. In this way, CrBₙ overcoat layer 85 has an outer surface 85a which may have improved properties (e.g., included but not limited to hardness) over the surface 84a had the overcoat layer 85 not been disposed thereon.

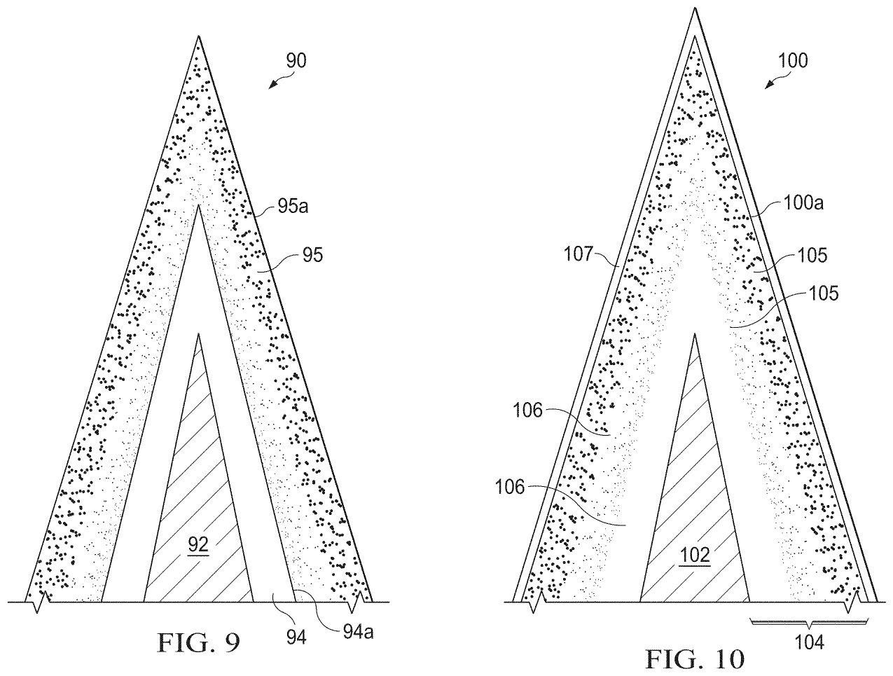

In FIG. 9, in accordance with the present invention, a modification of the embodiment of FIG. 8 is depicted indicating a blade edge region 90 having a CrBₙ overcoat composite layer 95 wherein the component materials are combined within the layer in concentration gradient. With an overcoat layer 95 comprising a composite of CrBₙ material and at least one other element or compound desirably comprised of additives, the gradient is desirably formed such that the additive/second component of this overcoat layer 95 increases in concentration in the direction from CrBₙ layer 94's outer surface 94a towards outer surface 95a of the blade edge. Accordingly, the CrBₙ material itself decreases in concentration in the direction from CrBₙ layer 94's outer surface 94a towards outer surface 95a. Thus, if desired properties are not present in CrBₙ layer 94, increases in the concentration of the ceramic material towards the surface 95a in the manner depicted in FIG. 9 (within the CrBₙ composite overcoat layer 95) could theoretically enhance performance factors including durability, adhesion, and reduced edge damage.

If desirable, the concentration gradient mentioned above may be reversed, in that the CrBₙ overcoat layer 95 would have an increasing concentration of the CrBₙ material in the direction from the outer surface 94a of the CrBₙ layer 94 towards outer surface 95a and the ceramic component of the CrBₙ overcoat layer 95 would have a decreasing concentration in the direction from CrBₙ layer 94's outer surface 94a towards outer surface 95a.

It should be noted that the presence of a concentration gradient as described in FIGS. 8 and 9 in the present invention is contemplated for CrBₙ layers as well, with or without the presence of a CrBₙ overcoat layer.

Moreover, the CrBₙ overcoat layer 95 may be a composite comprised of the CrBₙ material and one or more other elements or compounds, in lieu of or in addition to the ceramic mentioned herein to deliver specific performance benefits, such as but not limited to, hardness, adhesion, cutter forces, and/or lubriciousness.

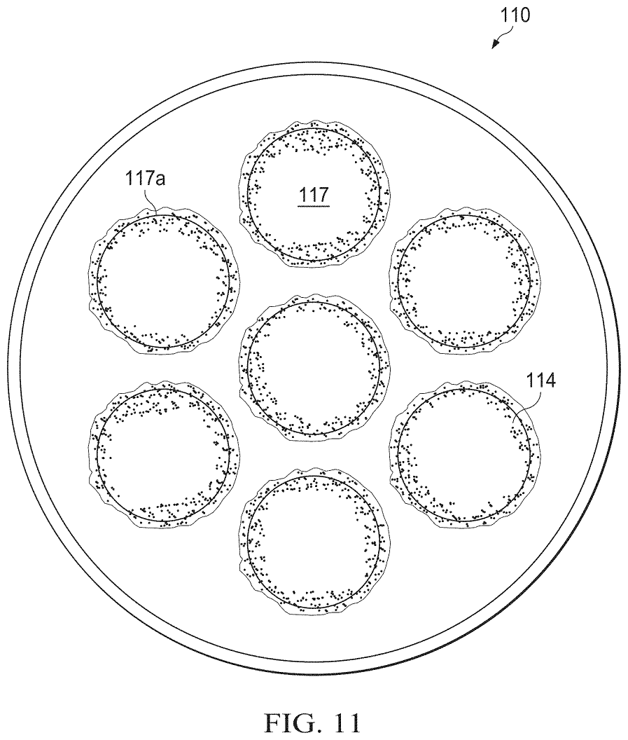

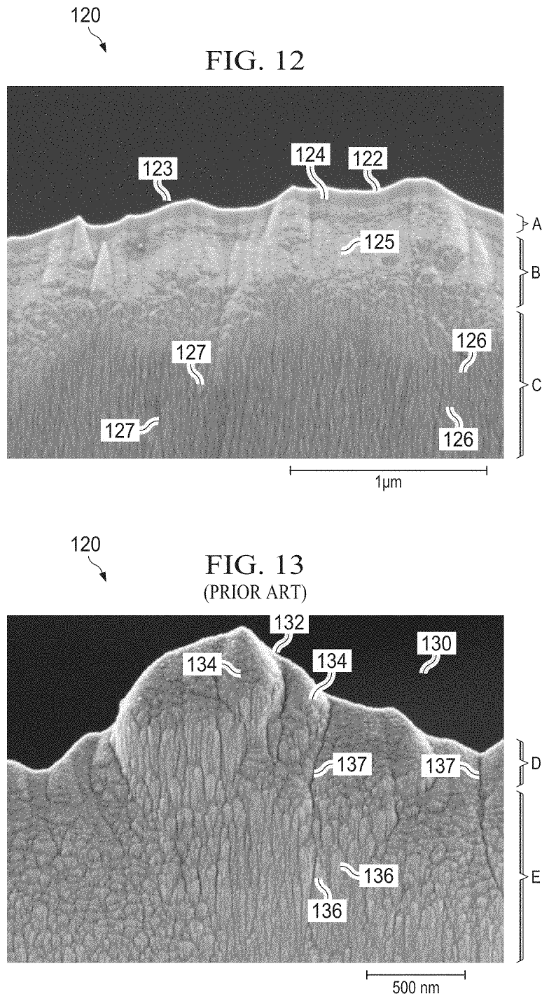

It is further contemplated in the present invention that the CrBₙ material layer 94 itself is formed having a concentration gradient. In the present invention, the amount of chromium or boron in the compound coating can increase in one direction or another within the CrBₙ coating layer. In FIG. 10, one embodiment depicts the amount of chromium 105 (represented by the increased gradient dot pattern) in the CrBₙ material coating 104 increases as the coating approaches the outer surface 100a of the razor blade 100 whereas the amount of boron 106 (represented by the area with the lack of dots) is minimized at the outer surface 100a. The converse is contemplated as well. The benefit of altering chromium levels in the hard CrBₙ material coating 104 to increase the concentration of chromium towards the outer surface 100a is to improve adhesion and durability of a PTFE material 107 disposed on top of CrBₙ material coating 104, while also reducing tip rounding effects.

The embodiments described herein have generally described linear blades with generally planar or straight edge regions and bevels. However, the present invention further contemplates the CrBₙ material 114 disposed on upper surfaces 117 of non-linear (shown as circular) blade unit edges 117a of substrate (not shown) in blade edge region 110 as depicted in FIG. 11. The CrBₙ material may be deposited using any of the processes described herein. It follows that any of the alternate embodiments shown in FIGS. 2-10 in conjunction with linear blades, can be similarly extended to the embodiment in FIG. 11. For instance, in conjunction with FIGS. 3 and 6, the non-linear blade edge of FIG. 11 may first be coated with an interlayer (not shown in FIG. 11) on top of which a CrBₙ material 114 layer is deposited.

The non-linear blade edges of the present invention may be of the types described in U.S. Pat. No. 4,807,360 entitled Shaving Device, issued on Feb. 28, 1989, and/or U.S. Pat. No. 4,875,228 entitled Shaving Device, issued on Oct. 24, 1989, both assigned to the assignee hereof, and incorporated by reference in their entireties.

FIG. 12 depicts an exemplary Scanning Electron Microscope (SEM) micrograph of a CrB₂ coated blade edge 120 of the present invention produced using PVD sputtering and a bias voltage on the blade substrate of −500 VDC. As can be seen, the blade 120 has unique properties. The tip areas of the blade 120 near ultimate tip 122 Area A unambiguously and compellingly show a dense, columnar-free area 124. The uniformity of the coating structure Area A throughout is beneficial. The ultimate tip 122 also has a very smooth outer surface 123 throughout. The dense, columnar-free area 124 together with the smooth tip surface 123 provides a desirable blade tip and edge, providing valuable hardness to the blade, so as to sustain less damage during shaving, to enhance shaving properties like cutter force and to improve overall durability. Area A extends from the ultimate tip and as shown it extends to about 0.10 micrometers or more from the ultimate tip 122. Area B, which is adjacent to Area A, while not as dense as Area A, also has beneficial properties in that it has a highly dense columnar structure 125. This area serves to provide additional structural support for the razor blade 120 and enhances the durability of the blade. Area C, which is furthest away from the ultimate tip 122 and just beyond Area B, can be seen as having a low dense columnar structure 126, lower than Area B, where structure 126 comprises column sides 127. Blade 120 of the present invention is very sharp comprising a cutter force of about 0.5 lbs. to about 1.0 lbs.

Comparing FIG. 12 to prior art FIG. 13, which depicts an exemplary Scanning Electron Microscope (SEM) micrograph of a coated blade edge 130 of the prior art produced using PVD sputtering of carbon instead of a CrB₂ material under substantially the same conditions as the blade 120, one can see that blade 130 has properties which are not as beneficial as those in FIG. 12. For instance, instead of comprising a dense, columnar free structure like Area A in FIG. 12, FIG. 13 comprises highly dense columnar structure in Area D and low dense columnar structure Area E without any columnar free areas. Area E is less dense than Area D which is closer to the tip area. However, even the compact areas 134 in Area D, are not desirably columnar free. Area E has columns 136 and defects 137 between them. Many of these defects 137 emanate from the ultimate tip 132 and run from the tip, perpendicularly down through Area D and down into Area E. Thus, ultimate tip 132 does not comprise as smooth a surface as tip 122. Such large defects of the prior art can lead to damage in the blade coating and are generally disadvantageous for shaving performance and durability. The cutter force of blade 130 is about 1.20 lbs. and is thus higher than that of the present invention of FIG. 12.

FIG. 14 depicts a series of micrographs A to E of various blade edges having only CrB₂ material deposited thereon using PVD sputtering methods. As shown in the SEM micrographs at 50K magnification in FIG. 14, there are five blades 1, 2, 3, 4, and 5, each with a CrB₂ material deposited thereon having an average coating thickness of about 780 Angstroms. The coatings on each of Blades 1-5 is deposited by sputtering using a different DC bias voltage on the blade substrate. Blade 1's coating was produced with the bias voltage on the substrate at zero voltage (0V), blade 2's coating was produced with the bias voltage on the substrate at negative 250V (−250 VDC). Blade 3's coating was produced with the bias voltage on the substrate at negative 500V (−500 VDC). Blade 4's coating was produced with the bias voltage on the substrate at negative 750V (−750 VDC). Blade 5's coating was produced with the bias voltage on the substrate at negative 1000V (−1000 VDC). While any type blade substrate profile or thickness of substrate is contemplated in the present invention, the thicknesses of the substrates of blades 1-5 shown in FIG. 14 are of the type generally described in U.S. Pat. No. 9,079,321, incorporated herein by reference in its entirety.

Accordingly, as can be seen, each of the coated blades has a tip area. The progression from micrograph A for Blade 1 to micrograph E for Blade 5 depicts a gradual transition from a rounder tip area 141 to a slimmer, very sharp tip area 145.

The tip areas 141-145 of the coated CrB₂ Blades 1-5, respectively of FIG. 14 have tip radii 141a, 142a, 143a, 144a, and 145a, respectively. Measurements of the tip radius were taken of the razor blades 1, 2, 3, 4, and 5 which were produced at different bias voltages and these measurements are determined based on the description below in FIG. 15. The resultant tip radius values are quantified in TABLE 1.

TABLE 1
Measurements of CrB₂ coated blades of FIG. 14

| | Blade 1 | | Blade 2 | | Blade 3 | | Blade 4 | | Blade 5 | |
|---|---|---|---|---|---|---|---|---|---|---|
| Bias Voltage | 0 | V | −250 | VDC | −500 | VDC | −750 | VDC | −1000 | VDC |
| Tip Radius | 748 | Angstroms | 258 | Angstroms | 292 | Angstroms | 289 | Angstroms | 258 | Angstroms |
| Tip angle | 69.6 | degrees | 70.3 | degrees | 60.6 | degrees | 54.8 | degrees | 51.9 | degrees |
| T0.5 μm | 0.47 | μm | 0.49 | μm | 0.47 | μm | 0.47 | μm | 0.44 | μm |
| T1.0 μm | 0.68 | μm | 0.70 | μm | 0.69 | μm | 0.72 | μm | 0.73 | μm |

With the only change being the bias voltage among the blades shown in FIG. 14, the blade tip radius characteristics listed in TABLE 1 vary from a value of 258 Angstroms to a value of 289 Angstroms as the negative bias is increased from −250V to −1000V but these values are substantially similar while the tip radius is much higher, namely at 748 A when the bias voltage is at 0V. It was also observed that the tip angle of each blade, the determination of which is described below with regard to FIG. 14b, varies greatly across the bias values as noted in the Table 1 above. It was discovered that the combination of tunability of tip radius and tip angle across the bias voltages provides novel blades with unique properties, such as a wide range of possible cutter forces with the ability to obtain very low cutter forces (e.g., 0.60 lbs.)

Accordingly, if a blunter, less sharp blade in a razor cartridge is desired, a process using a bias voltage of about 0V or between 0V and less than −250V may be implemented, whereas if a sharper or very sharp blade in a razor cartridge is desired, a process using any of the biases from −250V to −1000V can be implemented. The scope of the present invention contemplates that the bias voltage correlates to tip shape.

In summary, it was discovered that the application and varying of a negative bias to the substrate (e.g., blade) during sputtering causes increased bombardment of the substrate by ions in the plasma and that this not only affects the resultant tip shape of the blade as indicated in FIG. 14, but it also impacts the quality of the film making it denser, columnar-free, and smooth at the ultimate tip as indicated in FIG. 13.

FIG. 14a are diagrams of an average of multiple edge profiles for each of the blades depicted in FIG. 14. As can be seen, an average of multiple edge profiles for blade 1 produced at a bias voltage of 0V is shown as a solid line, blade 2 produced at a bias voltage of −250 VDC is shown as a dash dot dash line, blade 3 produced at a bias voltage of −500 VDC is shown as a dotted line, blade 4 produced at a bias voltage of −750 VDC is shown as a dash dot dash line, and blade 5 produced at a bias voltage of −1000 VDC is shown as a dash line. This diagram graphically represents the results from Table 1 above.

In FIG. 14b, an illustration depicting the determination of a tip angle is shown. This illustration demonstrates the concepts of the present invention, but it should be noted it is not to scale. The average ultimate tip 147 of the profiles of FIG. 14a is shown along with a tip angle α in the tip area. Tip angle α is determined by drawing or fitting lines L1 and L2 from the ultimate tip 147 down each bevel as shown in FIG. 14a. The lines generally stop at a distance D0.3 which is 0.3 μm from the ultimate tip. The included angle or tip angle α is measured between L1 and L2.

Referring now to FIG. 15, the tip radius is determined by first drawing a line 154 bisecting the coated blade 150 in half. Where line 154 bisects coated blade 150 a first point 155 is drawn. A second line 151 is drawn perpendicular to line 154 at a distance of 225 Angstroms from point 155. Where line 151 bisects coated blade 150 two additional points 156 and 157 are drawn. A circle 152 is then constructed from points 155, 156 and 157. The radius R of circle 152 represents the tip radius for coated blade 150.

Thus, as described above, with CrBₙ material being used on blade edges, there is a potential to provide a single coating solution to deliver optimized blade performance and simplified manufacturing.

The blade coating of the present invention is useful in any number of different types of cartridge units. It has been determined that when a hard, sharp, and durable razor blade cutting edge is desired in a cartridge where shaving forces are high, the blade of the present invention can withstand such forces, due in large part to the high quality of the blade coating. This can be useful in a razor cartridge that serves to cut hairs to a specific length, a trimmer, or a traditional razor cartridge.

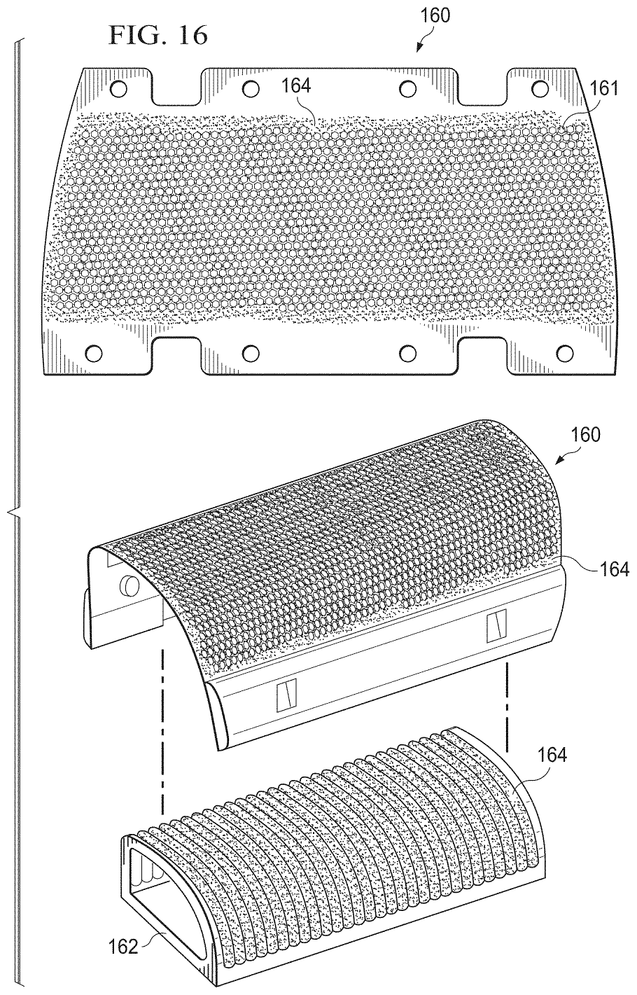

Referring to FIG. 16, an example of CrBₙ material 164 disposed on electric or dry shaver components, such as on outer and/or inner surfaces of a foil 160 component or dry shaver cutter elements 162 is shown in accordance with another embodiment of the present invention. An electric or dry razor generally consists of a set of oscillating or rotating blades or cutters 162, which are held behind a perforated metal foil 160 which prevents them from coming into contact with the skin and behaves much like the second blade in a pair of scissors. When the razor is held against the skin, the whiskers poke through the holes 161 in the foil 160 and are sliced by the moving cutters 162. While typically there is no lubricant applied in dry shaving to improve shave performance, the addition of a CrBₙ material or a CrBₙ coating, for instance, on the outer surface of the foil, may enhance the durability of the foil with a smooth, dense layer while also improving the performance of the shave and the durability of the cutting edge. Further, an advantage of having a CrBₙ coating on the inner surface of a foil (not shown) may generally include reduced edge wear resistance and reduced friction between the foil and cutters, which may provide a cooler shave, increased battery life and/or increased foil longevity. A CrBₙ coating 164 disposed on the outer surface of the cutter elements 162 themselves as shown in FIG. 16, may also desirably provide enhanced life or wear resistance of the cutters.

Thus, as described above, the CrBₙ material may be applied to dry shaver components such as foils and cutter elements and in turn provide improved shaving benefits such as reduced edge wear resistance and reduced friction.

The dimensions and values disclosed herein are not to be understood as being strictly limited to the exact numerical values recited. Instead, unless otherwise specified, each such dimension is intended to mean both the recited value and a functionally equivalent range surrounding that value. For example, a dimension disclosed as “40 mm” is intended to mean “about 40 mm.” The term “about” should be interpreted herein as within typical manufacturing tolerances.

Every document cited herein, including any cross referenced or related patent or application, is hereby incorporated herein by reference in its entirety unless expressly excluded or otherwise limited. The citation of any document is not an admission that it is prior art with respect to any invention disclosed or claimed herein or that it alone, or in any combination with any other reference or references, teaches, suggests or discloses any such invention. Further, to the extent that any meaning or definition of a term in this document conflicts with any meaning or definition of the same term in a document incorporated by reference, the meaning or definition assigned to that term in this document shall govern.

While particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. A razor blade apparatus comprising:
a sharpened substrate having at least one material comprising a compound of chromium and boron, (CrBₙ) disposed thereon, wherein an atomic percentage of boron ranges from greater than zero atomic percent to less than 100 atomic percent of said compound.

2. The razor blade apparatus of claim 1 wherein said at least one CrBₙ material is directly disposed on the sharpened substrate.

3. The razor blade apparatus of claim 2 wherein said at least one CrBₙ material forms at least one layer on said sharpened substrate.

4. The razor blade apparatus of claim 3 wherein one or more interlayers are disposed between said at least one CrBₙ layer and the sharpened substrate, one or more overcoat layers are disposed on top of said at least one CrBₙ layer, or both.

5. The razor blade apparatus of claim 4 wherein said one or more interlayers and said one or more overcoat layers comprise polymeric material, niobium, chromium, platinum, titanium, silicon, tantalum, tungsten, molybdenum, carbon, boron, or any combination or alloys thereof.

6. The razor blade apparatus of claim 4 wherein at least one polymeric material is disposed on top of the at least one CrBₙ layer, or on top of said one or more overcoat layers, or any combination thereof.

7. The razor blade apparatus of claim 6 wherein said at least one polymeric material comprises PTFE.

8. The razor blade apparatus of claim 4 wherein said one or more overcoat layers is comprised of a CrBₙ material and a second component.

9. The razor blade apparatus of claim 8 wherein said second component is one or more of a polymeric material, ceramic, metal, silicon, boron, carbon, or any combination thereof.

10. The razor blade apparatus of claim 8 wherein said one or more overcoat layers comprises an increasing concentration of said second component in a direction towards an outer surface of the substrate or a decreasing concentration of said second component in a direction towards an outer surface of the substrate.

11. The razor blade apparatus of claim 1 wherein the at least one CrBₙ material is disposed on the sharpened substrate via physical vapor deposition or chemical vapor deposition.

12. The razor blade apparatus of claim 1 wherein the sharpened substrate is comprised of stainless steel, metal, ceramic, composite, diamond, silicon, polymeric material, glass, or any combination thereof.

13. The razor blade apparatus of claim 12 wherein said substrate is martensitic stainless steel having a carbide density of about 90 carbides per 100 square micrometers to about 1000 carbides per 100 square micrometers.

14. The razor blade apparatus of claim 1 wherein the sharpened substrate is on a blade edge of the razor blade wherein said blade edge is linear, non-linear, or any combination thereof.

15. The razor blade apparatus of claim 3 wherein said at least one CrBₙ layer has a hardness greater than or equal to 15 GPa.

16. The razor blade apparatus of claim 3 wherein said at least one CrBₙ layer comprises a substantially dense, smooth, columnar-free structure, highly dense columnar structure, low dense columnar structure, or any combination thereof.

17. The razor blade apparatus of claim 1 wherein a tip radius of said razor blade ranges from 100 Angstroms to 1000 Angstroms.

18. The razor blade apparatus of claim 1 wherein a cutter force of said razor blade ranges from 0.5 lbs. to 2 lbs.

19. The razor blade apparatus of claim 3 wherein a thickness of said layer ranges from 50 Angstroms to 5000 Angstroms.

20. A method of making a razor blade comprising:
providing a sharpened substrate; and
depositing at least one layer of CrBₙ material on said sharpened substrate.

21. The method of claim 20 wherein said deposition comprises sputtering.

22. The method of claim 20 wherein said deposition step comprises Physical Vapor Deposition, Chemical Vapor Deposition, or a combination thereof.

23. The method of claim 22 wherein said deposition comprises a negative voltage on the substrate.

24. The method of claim 23 wherein the negative voltage ranges from less than or equal to 0V to negative 1000V (−1000 VDC).

25. The method of claim 21 wherein said depositing step comprises providing one or more targets.

26. The method of claim 25 wherein said one or more targets comprise a homogeneous mixed material comprising chromium and boron.

27. The method of claim 25 wherein said one or more targets comprises two targets, one comprising chromium and one comprising boron.

28. The method of claim 20 wherein a thickness of said layer ranges from 50 Angstroms to 5000 Angstroms.

29. The method of claim 20 wherein a cutter force of an edge of said razor blade ranges from 0.5 lbs. to 2 lbs.

30. The method of claim 20 wherein a tip radius of said razor blade ranges from 100 Angstroms to 1000 Angstroms.

31. The method of claim 23 wherein said at least one layer of CrBₙ material comprises a substantially dense, smooth, columnar-free structure, highly dense columnar structure, low dense columnar structure, or any combination thereof, or any combination thereof.

32. The method of claim 23 wherein at said negative voltage ranges between −250 VDC and −1000 VDC, a tip radius produced ranges from 200 to 300 Angstroms.

33. The method of claim 23 wherein at said negative voltage ranges between 0 VDC and −250 VDC, a tip radius produced is greater than 300 Angstroms.

34. The method of claim 23 wherein at a thickness of said at least one layer of CrBₙ material ranges from 300 Angstroms to 800 Angstroms and a negative voltage ranges from about −250 VDC and −1000 VDC, a cutter force of said razor blade is produced ranging from about 0.6 lbs. to about 0.98 lbs.

35. A method of coating a razor blade comprising the steps of
providing a sharpened substrate;
depositing at least one layer of material on said sharpened substrate, said deposition comprising placing a voltage on the substrate; and
selecting from within a first voltage range on the substrate to produce a first razor blade edge or selecting from within a second voltage range on the substrate to produce a second razor blade edge, said second razor blade edge being sharper than the first razor blade edge.

36. The method of claim 35 wherein said first razor blade edges have tip radii larger than tip radii of said second blade edges.

37. The method of claim 35 wherein said first and second voltage ranges range from 0V to negative 1000V (−1000 VDC).

38. The method of claim 35 wherein said first voltage range ranges between 0 VDC and −250 VDC.

39. The method of claim 38 wherein a first tip radius of said selected first razor blade edge is greater than 300 Angstroms.

40. The method of claim 38 wherein a cutter force of said first razor blade edge is greater than 1 lbs.

41. The method of claim 35 wherein said second voltage range ranges between about −250 VDC and −1000 VDC.

42. The method of claim 41 wherein a second tip radius of said second blade edge produced is less than 300 Angstroms.

43. The method of claim 41 wherein a cutter force of said second blade edge ranges from about 0.5 lbs. to about 1 lb.

44. The method of claim 35 wherein said at least one layer of material comprises a CrBₙ material
